(19) United States
(12) Patent Application Publication
(10) Pub. No.: US 2008/0118733 A1
(43) Pub. Date: May 22, 2008

(54) Nitride semiconductor ingot, nitride semiconductor substrate fabricated from the same and method for making nitride semiconductor ingot

(75) Inventor: Yuichi Oshima, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 11/806,983

(22) Filed: Jun. 5, 2007

(30) Foreign Application Priority Data
Nov. 22, 2006 (JP) 2006-315335

(51) Int. Cl. B32B 9/04; C30B 25/08

(52) U.S. Cl. 428/220; 117/88

(57) ABSTRACT

A nitride semiconductor ingot is formed of a nitride semiconductor, and has a length of more than 20 mm and a diameter of not less than 50.8 mm. The nitride semiconductor ingot includes no cracks in a portion except 3 mm from an outermost thereof.

The present application is based on Japanese patent application No. 2006-315335, the entire contents of which are incorporated herein by reference.

### BACKGROUND OF THE INVENTION

1. Field of the Invention

This invention relates to a nitride semiconductor ingot which can be widely applied to fabrication of a substrate for a nitride semiconductor device, a nitride semiconductor substrate produced from the nitride semiconductor ingot and a method for making the nitride semiconductor ingot.

2. Description of the Related Art

Nitride semiconductors such as gallium nitride (GaN), indium gallium nitride (InGaN), gallium aluminum nitride (AlGaN) are highlighted as materials for a blue light emitting diode (LED) and a laser diode (LD). Since the nitride semiconductor is excellent in heat resistance and environment resistance, the application of the nitride semiconductor to electronic device elements has been started.

At present, a sapphire substrate is practically and widely used as a substrate to grow the nitride semiconductor thereon, where the nitride semiconductor is in general epitaxially grown on the single crystal sapphire substrate by MOPVE (metalorganic vapor phase epitaxy) etc.

However, since the sapphire substrate has a different lattice constant from that of GaN, it is impossible to obtain a single crystal film by growing the nitride semiconductor directly on the sapphire substrate.

Therefore, a method is disclosed that a buffer layer such as AlN and GaN is formed on the sapphire substrate at a relatively low temperature to buffer a lattice strain, and a nitride semiconductor is grown on the low temperature growth buffer layer (See, e.g., U.S. Pat. No. 5,733,796 and U.S. Pat. No. 6,362,017).

By using the low temperature growth buffer layer, the single crystal epitaxial growth of GaN nitride semiconductor can be realized.

However, even in the method, since the lattice mismatch between the sapphire substrate and the epitaxial growth crystal cannot be eliminated, the epitaxial layer includes a number of defects. Thus, the defect becomes an obstacle to producing a LD and a high-brightness LED.

For the above reasons, a nitride semiconductor free-standing substrate is highly desired. In case of GaN, a large ingot thereof is difficult to be grown from a melt thereof unlike in case of Si or GaAs. Therefore, various methods such as a ultrahigh temperature and pressure method, a flux method and a hydride vapor phase epitaxy (HVPE) method have been tried. Of the above methods, the HVPE method is often used to develop the GaN substrate and the substrate thus developed has been distributed in the market, although gradually.

The GaN substrate currently distributed in the market is produced by growing a thick film of GaN by the HVPE method on a hetero-substrate such as sapphire and GaAs, and by eliminating the hetero-substrate after the growth.

However, in the above method, it is necessary to prepare one base hetero-substrate to produce one GaN substrate so that not more than ten GaN substrates can be only taken in one cycle by using the HVPE method. Thus, the production cost must be higher than a Si or GaAs substrate where many substrates can be cut together from a large ingot. Therefore, the price of the GaN substrate is extremely higher than the other semiconductor substrates so that it can be a large obstacle to spread of the GaN substrate.

One way to reduce the production cost of the GaN substrate may be considered a method in which a thick GaN ingot formed by the HVPE method is sliced to produce many substrates collectively as done in the conventional production method for semiconductor substrate. In this method, it is unnecessary to prepare the base substrate any more and the setup process for the HVPE method can be omitted so that a substantial cost reduction effect may be expected.

However, as a matter of fact, the nitride semiconductor ingot obtained by the conventional method is limited to a thickness of about 20 mm at the most even if the crystalline quality is neglected, and if exceeding 20 mm the ingot will be subjected to significant crack generation. As a result, it is difficult to cut many nitride semiconductor substrates from the nitride semiconductor ingot. Therefore, the cost reduction cannot be achieved.

### SUMMARY OF THE INVENTION

It is an object of the invention to provide a nitride semiconductor ingot that can allow a cost reduction in producing nitride semiconductor substrates and a method for making the nitride semiconductor ingot.

It is a further object of the invention to provide a substrate obtained from the nitride semiconductor ingot.

(1) According to one aspect of the invention, a nitride semiconductor ingot comprises:

a nitride semiconductor;

a length of more than 20 mm; and

a diameter of not less than 50.8 mm,

wherein the nitride semiconductor ingot includes no cracks in a portion except 3 mm from an outermost thereof.

In the above invention (1), the following modifications and changes can be made.

(i) The nitride semiconductor ingot further comprises a minimum value in dislocation density being not more than 1.5×10⁶ cm⁻².

(2) According to another aspect of the invention, a nitride semiconductor substrate comprises:

a diameter of not less than 25.4 mm; and

a thickness of not less than 0.2 mm,

wherein the substrate is produced by slicing a nitride semiconductor ingot, and

the nitride semiconductor ingot comprises a nitride semiconductor, a length of more than 20 mm, and a diameter of not less than 50.8 mm, wherein the nitride semiconductor ingot includes no cracks in a portion except 3 mm from an outermost thereof.

(3) According to another aspect of the invention, a nitride semiconductor substrate comprises:

a diameter of not less than 25.4 mm; and

a thickness of not less than 0.2 mm,

wherein the substrate is produced by slicing a nitride semiconductor ingot,

the nitride semiconductor ingot comprises a nitride semiconductor, a length of more than 20 mm, and a diameter of not less than 50.8 mm, wherein the nitride semiconductor ingot includes no cracks in a portion except 3 mm from an outermost thereof, and

the nitride semiconductor substrate further comprises an off-angle variation of not more than 0.05 degrees in a plane of the substrate, where the off-angle variation is defined as a difference between a maximum value and a minimum value of off-angle in the plane.

In the above invention (3), the following modifications and changes can be made.

(ii) The nitride semiconductor substrate further comprises a dislocation density being not more than 1.5×10⁶ cm⁻².

(4) According to another aspect of the invention, a method for making a nitride semiconductor ingot comprises the steps of:

disposing a seed substrate comprising a thickness of 100 μm to 250 μm in a growth reactor; and

forming a nitride semiconductor on the seed substrate to grow a nitride semiconductor ingot,

wherein the nitride semiconductor ingot comprises a length of more than 20 mm and a diameter of not less than 50.8 mm, and the nitride semiconductor ingot includes no cracks in a portion except 3 mm from an outermost thereof.

(5) According to another aspect of the invention, a method for making a nitride semiconductor ingot comprises the steps of:

disposing a seed substrate comprising a curvature radius in lattice plane warpage of not less than 20 m in a growth reactor; and

forming a nitride semiconductor on the seed substrate to grow a nitride semiconductor ingot,

wherein the nitride semiconductor ingot comprises a length of more than 20 mm and a diameter of not less than 50.8 mm, and the nitride semiconductor ingot includes no cracks in a portion except 3 mm from an outermost thereof.

(6) According to another aspect of the invention, a method for making a nitride semiconductor ingot comprises the steps of:

disposing a seed substrate comprising a dislocation density of not more than 2×10⁶ cm⁻² in a growth reactor; and

forming a nitride semiconductor on the seed substrate to grow a nitride semiconductor ingot,

wherein the nitride semiconductor ingot comprises a length of more than 20 mm and a diameter of not less than 50.8 mm, and the nitride semiconductor ingot includes no cracks in a portion except 3 mm from an outermost thereof.

(7) According to another aspect of the invention, a method for making a nitride semiconductor ingot comprises the steps of:

disposing a seed substrate in a growth reactor;

disposing a Ga (gallium) in the growth reactor and introducing an HCl gas therein;

introducing an NH₃ in the growth reactor;

controlling a temperature condition such that a temperature at a GaCl generation portion where a GaCl is generated from the HCl and the Ga is substantially equal to a temperature at a growth portion where a GaN is deposited in the growth reactor, and

growing the nitride semiconductor ingot on the seed substrate under the temperature condition, the nitride semiconductor ingot comprising a length of more than 20 mm and a diameter of not less than 50.8 mm and including no cracks in a portion except 3 mm from an outermost thereof.

(8) According to another aspect of the invention, a method for making a nitride semiconductor ingot comprises the steps of:

disposing a seed substrate in a growth reactor;

introducing a GaCl in the growth reactor;

introducing an NH₃ in the growth reactor;

controlling a growth rate condition such that a variation in growth rate of the ingot to be grown based on a supply of the GaCl and the NH₃ in the growth reactor is not more than 5%, and

growing the nitride semiconductor ingot on the seed substrate under the growth rate condition, the nitride semiconductor ingot comprising a length of more than 20 mm and a diameter of not less than 50.8 mm and including no cracks in a portion except 3 mm from an outermost thereof.

In the above inventions (4) to (8), the following modifications and changes can be made.

(iii) The grown nitride semiconductor ingot comprises a minimum value in dislocation density of not more than 1.5×10⁶ cm ⁻².

### Advantages of the Invention

According to the invention, a nitride semiconductor crystal with a long shape of more than 20 mm in length, high quality and no cracks can be grown, so that the production cost of the nitride semiconductor substrate can be reduced.

### BRIEF DESCRIPTION OF THE DRAWINGS

The preferred embodiments according to the invention will be explained below referring to the drawings, wherein:

FIG. 1 is a graph showing the relationship between a critical thickness of a nitride semiconductor ingot and a crystal lattice warpage of a seed substrate thereof;

FIG. 2 is a graph showing a dependency of emission wavelength (photon energy) variation to off-angle variation; and

FIG. 3 is an explanatory view schematically showing an HVPE reactor used to make a nitride semiconductor ingot in a first preferred embodiment according to the invention.

### DETAILED DESCRIPTION OF THE PREFERRED EMBODIMENTS

The inventor has taken into account that a critical thickness where a crack starts to occur in an ingot is determined according to the intensity of stress caused by a defect density gradient in the thickness direction and a variation in crystal orientation of a GaN substrate used as a seed crystal, and that the crack starts to occur when the thickness of the ingot exceeds the critical thickness. The inventor keenly studied the cause of stress generated during the growth of the GaN ingot, so that he has found the causes and measures as described in the following paragraphs (1) to (4).

### (1) In-Plane Variation of Crystal Orientation

Generally, a GaN substrate obtained by the growth process of Volmer-Weber mode (i.e., a three-dimensional island-shaped film is formed in the early stage of film growth process) such as HVPE growth on a hetero-substrate has a warpage concaved as seen from above the surface. Even when the surface is polished to be apparently planarized, the lattice plane of the crystal remains warped and includes an in-plane variation of crystal orientation therein. If such a substrate is used as a seed substrate to grow an ingot, since the area of growth surface is reduced although the number of lattice points does not change, a compression stress may be caused. For example, when a GaN substrate with a thickness of 3.5 mm is bent at a curvature radius of 30 m, compression stress on the surface is estimated to be about 17.5 MPa from the simple strain amount and Hooke's law. The critical thickness h_{c} is inversely proportional to the square of stress σ, and represented by:

$${h}_{c} = \frac{Γ E}{Z ( 1 - {ν}^{2} ) {σ}^{2}}$$

where Γ is a generation energy of crack per unit length, i.e., about 2 J/m², E is Young's modulus and reported about 150 GPa, ν is Poisson's ratio, i.e., about 0.38, and Z is a coefficient varying dependent on the form of crack, i.e., about 2 in case of random arrangement. When numerical values are substituted for each parameter, hc is calculated about 0.56 mm, which is smaller than the thickness, 3.5 mm. This means that the crystal can be cracked. In fact, since the warpage of whole crystal can be relaxed by the compression stress, it is assumed that the actual critical thickness becomes much larger than the calculated value. In any event, the critical thickness is very sensitive to the stress and the stress becomes larger as the warpage of the seed substrate increases (i.e., the curvature radius thereof decreases).

In view of this, in order to suppress the generation of stress, the inventor found two methods of “using a seed substrate with a small warpage (or a narrow crystal orientation distribution)” and “using a seed substrate as thin as possible”.

### (1-1) Using a Seed Substrate With a Small Crystal Orientation Distribution

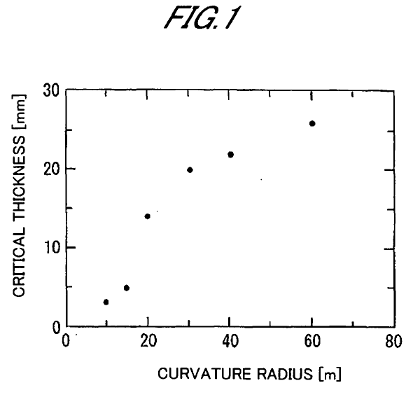

FIG. 1 is a graph showing a study result of correlation between the curvature radius of the lattice warpage of a seed substrate and the critical thickness of an ingot (i.e., the maximum thickness of the ingot where to allow the ingot to have no cracks in a portion except 3 mm from the outermost) in case of producing the ingot by using the seed substrate.

The ingot was produced in a condition similar to that of the first embodiment described later, except that only the curvature radius of seed substrate was changed. It was found that, by using the seed substrate with a curvature radius of not less than 20 m, the critical thickness can be drastically increased to more than 14 mm. Further, it was found that, by using the seed substrate with a curvature radius of not less than 30 m, an unprecedented critical thickness of more than 20 mm can be obtained. With regard to the warpage, a seed substrate originally having a small warpage may be used. Alternatively, even a seed substrate having a large warpage may be used by being corrected by mechanical pressing etc.

### (1-2) Using a Seed Substrate as Thin as Possible

Even when the internal stress occurs, it can be relaxed by deforming the seed substrate. However, when the seed substrate is thick and has a high stiffness, the stress cannot be relaxed so that the critical thickness becomes small. In case of using a thin seed substrate, it is deformable rapidly in response to the occurrence of stress so that the stress can be relaxed. Then, the lattice plane comes near a flat surface so that a further occurrence of stress can be also prevented. It is not necessarily appropriate to suggest to what extent the seed substrate has to be reduced in thickness since it depends on the curvature radius of lattice or the growth conditions etc. However, when it is not more than 250 μm, a remarkable effect can be secured. In principle, there is no lower limit of thinness but it is preferable that it has a thickness of not less than 100 μm so as not to be broken in handling.

(2) fDislocation Density Gradient

It is known that the dislocation density decreases according as the thickness of the grown GaN increases. When a dislocation with an edge component decreases, the extra-half-lattice plane decreases. Therefore, according as the growth is advanced, the crystal volume may decrease and the stress may be caused thereby.

Since it is assumed that the reduction rate of dislocation is inversely proportional to the square root the dislocation density, it is important that a substrate originally with a small dislocation density is used as a seed substrate. This effect appears remarkably at a lower dislocation density. It is not necessarily appropriate to suggest a tolerance thereof since it depends on the growth conditions of the ingot etc. It is often the case that good results can be obtained generally in case of a dislocation density of not more than 2×10⁶ cm⁻². In other words, although there is a critical thickness corresponding to the dislocation density of a seed substrate to be used, the dislocation density decreases gradually by repeating the ingot growth within the range of critical thickness so that a long ingot can be progressively grown.

### (3) Concentration Gradient of Impurity or Point Defect

If Ga and N sites are replaced with an impurity with a larger ion radius than them, the average lattice constant increases. On the other hand, if replaced with an impurity with a smaller ion radius than them, the average lattice constant decreases. In like manner, a vacancy may cause such a volume change. Therefore, if a concentration distribution of the impurity or point defect exists in the crystal, the internal stress will be caused. For example, the concentration distribution may be caused by a spatial ununiformity due to the ununiform stream of raw material and dopant gas, and a temporal ununiformity due to the temporal variation of growth rate etc. associated with the movement of growth surface position according to deposition of polycrystal on a raw material nozzle and a reactor wall or super thickened GaN.

In order to prevent the concentration distribution, a flow control is effective in improving the spatial uniformity, and inhibition of the polycrystal deposition by gas purge and a mechanism for setting back the crystal position to meet the growth rate are effective in improving the temporal evenness. The prevention effect can be often achieved remarkably by controlling a variation in growth rate during the growth to be not more than 5%, although it depends on the concentration of the impurity existing in the reactor and on the growth conditions such as V/III ratio.

### (4) Temperature Distribution

If a nonlinear temperature distribution exists in the growth direction or in the in-plane direction of crystal, thermal stress may be generated which causes deformation of crystal or occurrence of crack. Therefore, it is very important to uniform the temperature distribution in the reactor.

By combining the above measures, the internal stress of the nitride semiconductor ingot can be remarkably suppressed so that the long crystal can be grown without a crack.

In a semiconductor wafer, “an angle defined between a surface and a low-index surface with the highest parallelization degree to the surface” is generally called “off-angle”. The off-angle is a parameter that seriously affects the characteristics of film to be epitaxially grown thereon. If the off-angle is different, the density of a dangling-bond or step appearing on the surface varies so that the incorporation quantity of impurity and the optimum growth rate to obtain a smooth film may be changed.

For example, even when an InGaN light emitting layer is grown under the same conditions, the incorporation quantity of In and Ga into the crystal becomes different if the off-angle of substrate is different. Therefore, the in-plane variation of the off-angle may cause the composition distribution of InGaN as an active layer of light emitting element to generate ununiformity in emission. Although a tolerance in wavelength variation associated with the emission ununiformity depends on the specification required for the device, a tolerance of not more than 20 meV in terms of optical energy is acceptable in most cases.

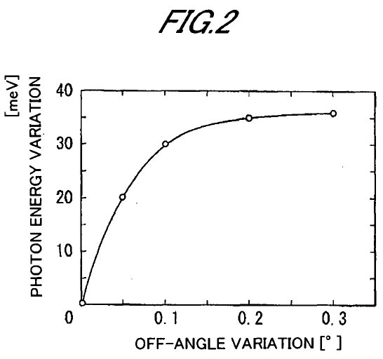

FIG. 2 is a graph showing a change in emission wavelength (photon energy) variation due to off-angle variation. As shown clearly in FIG. 2, the variation of photon energy decreases according as the variation of off-angle decreases. In particular, in case of an off-angle variation not more than 0.05 degrees, the photon energy variation decreases remarkably to less than 20 meV. Thus, it is preferable that the off-angle in-plane variation is set to be not more than 0.05 degrees to reduce the photon energy variation.

### First Embodiment

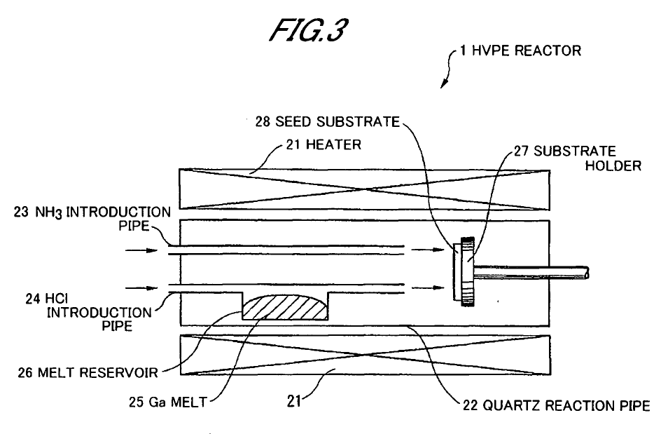

As shown in FIG. 3, the HVPE reactor 1 is a hot wall type growth reactor to heat the whole of quartz reaction pipe 22 by a heater 21 disposed outside. By using the HVPE reactor 1, a nitride semiconductor ingot was grown while using a GaN substrate with a diameter of 50.8 mm (=2 inches) and a thickness of 200 μm as a seed substrate. When the lattice plane warpage of seed substrate was searched by X-ray diffraction method, the curvature radius was about 40 m.

GaCl was used as III group material. GaCl was produced by mutually reacting HCl gas introduced with a carrier gas from the upstream part of quartz reaction pipe 22 through a HCl introduction pipe 24 and Ga melt 25 in a melt reservoir (a production portion) 26 disposed inside of the pipe 22. V group material was introduced through a NH₃ introduction pipe 23 independently of the III group material, and was mixed to the III group material just before the substrate, so that GaN was deposited on the seed substrate (a deposition portion) 28 mounted on a substrate holder 27.

The HVPE growth condition was set as GaCl partial pressure is 4×10⁻² atm, NH₃ partial pressure is 3.6×10⁻¹ atm, and growth temperature is 1073° C. GaCl was produced by passing HCl gas through a Ga melt boat disposed at the upstream part of growth portion. The temperature of Ga melt portion was 857° C. The reactor pressure was atmospheric pressure, and the designed growth rate was 1.2 mm/h. According to the condition described above the growth of GaN ingot was tried for 3 hours, so that a crystal of 4.5 mm in thickness without a crack at all was obtained. The growth rate was increased in proportion to time, so as to become 1.8 mm/h just before the growth end.

Further, when a growth of ingot with a longer length was tried, a crystal with the longest length of 22 mm and no cracks in a portion thereof except 3 mm from the outermost was obtained. It is assumed that the reason why the long length growth could be achieved is based on the fact that the generation of stress associated with the growth was small since the crystal orientation distribution of seed substrate was small, and the warpage was further recovered by small stress since the seed substrate was thin so that new generation of stress can be simultaneously prevented. When the dislocation density of obtained crystal was determined by the cathode luminescence method, though it was originally 5×10⁶ cm⁻² in the seed substrate, it was reduced according as the thickness of the grown crystal increases such that it becomes 7×10⁵ cm⁻² at the thickest position.

The ingot was grown by using the substrate with a thin thickness and a small warpage, so that an ingot with a diameter of 50.8 mm and a length of 22 mm (which is an unprecedented length of not less than 20 mm) could be obtained.

### COMPARATIVE EXAMPLE

On the other hand, an ingot of 3.6 mm in thickness was grown by the HVPE method at the same growth condition, using GaN substrate with a diameter of 50.8 mm and a thickness of 420 μm as a seed substrate. The lattice plane warpage of seed substrate was searched by X-ray diffraction method, so that the curvature radius as about 10 m.

After the growth, when a crystal was took out from the reactor, a number of cracks were generated near the surface and even in a portion thereof except 3 mm from the outermost. From the observation of cross-section, it was estimated that the cracks started to be generated from the time when the thickness exceeded about 3 mm. Further, the whole thickness of crystal was 4.5 mm, the thickness being thicker than the originally designed value. From the observation of material nozzle after the growth, it was found that a great deal of poly crystal GaN adhered to the edge of nozzle, so that the nozzle was increased in length to the extent of about 7 mm. It is assumed that the increase of the growth rate was caused by that the growth surface position neared the nozzle due to the extension of nozzle and the increase of thickness. When the total amount of impurities and vacancies in the head and tail of growth crystal was searched by a SIMS (Secondary Ion Mass Spectrometry) analysis and a positron annihilation method, it was estimated that the amount was 2×10¹⁸ cm⁻³in the head and 4×10¹⁸ cm⁻³ in the tail. When the dislocation density of the obtained crystal was determined by the cathode luminescence method, though it was originally 5×10⁶ cm⁻² in the seed substrate, it was reduced according as the thickness of the grown crystal increases such that it becomes 1×10⁶ cm⁻² at a position of 2.8 mm from the upper surface of the seed substrate, but thereafter it increases adversely such that it becomes 3×10⁶cm⁻² at the outermost surface, 4.5 mm from there. It is assumed that the increase of dislocation was caused to relax the stored stress.

### Advantages of the First Embodiment

According to the first preferred embodiment described above, the following advantages are obtained.
(1) Internal stress in GaN ingot is remarkably relaxed so that the GaN ingot with an unprecedented long length can be obtained and the cost reduction can be achieved.
(2) Internal stress in GaN ingot is remarkably relaxed so that the high quality GaN ingot can be obtained.

### Second Embodiment

GaN ingot obtained in the first preferred embodiment was sliced by a wire saw, and the both surfaces of the slices were ground, so that GaN s of 50.8 mm in diameter and of 200 μm in thickness were newly obtained. A growth of ingot was tried by HVPE method, using the substrate as a seed substrate. The dislocation density of seed substrate was 7×10⁵ cm⁻². Also in the second preferred embodiment, the growth rate was increased in proportion to time, so as to become 1.8 mm/h just before the growth end. When the lattice plane warpage of seed substrate was searched by X-ray diffraction method, the curvature radius was about 60 m.

When a growth of GaN ingot was tried at the growth condition similar to the first preferred embodiment, an ingot with the longest length of 26 mm and no cracks in a portion thereof except 3 mm from the outermost was obtained, so that a further long length growth could be achieved. It is assumed that the reason why the further long length growth could be achieved is based on the fact that the crystal orientation distribution of seed substrate became smaller, and the change rate of dislocation density associated with the increase in thickness became small since the dislocation density of seed substrate was small. When the dislocation density of obtained crystal was determined by the cathode luminescence method, it was reduced to 5×10⁵ cm⁻² at a position of 26 mm from the surface of the seed substrate.

As described above, the ingot was grown by using a substrate with a low dislocation density in combination, so that an ingot with a diameter of 50.8 mm and a length of 26 mm (which is an unprecedented length of not less than 25 mm) can be obtained.

### Advantages of the Second Embodiment

According to the second preferred embodiment described above, similarly to the first preferred embodiment, the internal stress in GaN ingot is remarkably relaxed, so that the GaN ingot with an unprecedented long length can be obtained, the cost reduction can be achieved, and the high quality GaN ingot and GaN substrate can be obtained.

### Third Embodiment

When a growth of GaN ingot was tried at the growth condition that the temperature of melt portion (that is, GaCl generation portion) of HVPE growth reactor was set to 1073° C. equal to that of growth portion (deposition portion), the reactor temperature distribution was equalized, and GaN substrate of 200 μm in thickness was used as the seed substrate similarly to the second preferred embodiment, an ingot with the longest length of 29 mm and no cracks in a portion except 3 mm from the outermost was obtained, so that a further long length growth could be achieved. Also in the third preferred embodiment, the growth rate was increased in proportion to time, so as to become 1.8 mm/h just before the growth end. It is assumed that the reason why the further long length growth could be achieved is based on the fact that the reactor temperature distribution was improved, so that the heat stress was decreased. Actually, when the total amount of impurities and vacancies concentration in the ingot was determined by the SIMS (Secondary Ion Mass Spectrometry) analysis and the positron annihilation method, the amount was 4×10¹⁸ cm⁻³ in the head and tail respectively, and it was found that the ingot was extremely homogeneous. When the dislocation density of the obtained crystal was determined by the cathode luminescence method, it was reduced to 3×10⁵ cm⁻² at a position of 29 mm from the surface of the seed substrate.

As described above, the ingot was grown in the improved temperature condition, so that an ingot with a diameter of 50.8 mm and a length of 29 mm (which is an unprecedented length of not less than 25 mm) could be obtained.

### Advantages of the Third Embodiment

According to the third preferred embodiment described above, similarly to the first preferred embodiment, the internal stress in GaN ingot is remarkably relaxed, so that the GaN ingot with an unprecedented long length can be obtained, the cost reduction can be achieved, and the high quality GaN ingot and GaN substrate can be obtained.

Further, when a growth of ingot was tried at the growth condition similar to that of the third preferred embodiment except that the seed substrate of 250 μm in thickness was used, it was confirmed that also in this case an ingot with a diameter of 50.8 mm and the longest length of 29 mm and no cracks in a portion except 3 mm from the outermost can be obtained

### Fourth Embodiment

When a growth of GaN ingot was tried at the growth condition similar to that of the third preferred embodiment except that a purge mechanism for preventing the deposition of poly crystal was additionally installed in the material nozzle of HVPE reactor, and the substrate position was set backed at the speed equal to the growth rate, so that the growth surface could be controlled so as to locate always at the same position in the reactor, an ingot with the longest length of 31 mm and no cracks in a portion except 3 mm from the outermost was obtained, so that a further long length growth could be achieved. It is assumed that the reason why the further long length growth could be achieved is based on the fact that the crystal length conformed to the designed value, the variation of growth rate during the growth could be prevented, and the generation of internal stress due to the variation of impurities and vacancies concentration could be prevented. When the dislocation density of obtained crystal was determined by the cathode luminescence method, it was reduced to 2×10⁵ cm⁻² at a position of 31 mm from the upper surface of the seed substrate.

The ingot was cut by a multiwire saw, and thirty five as-slice-wafers of 0.6 mm in thickness were obtained. The both surfaces thereof were ground and the outer shapes thereof were arranged, so that the GaN substrates with a diameter of 50.8 mm and a thickness of 0.42 mm were obtained. Any dislocation density of the obtained GaN substrates was not more than 3×10⁵ cm⁻², and it was found that the substrates have an extremely high quality.

As described above, a variation in time was eliminated, so that an ingot with a diameter of 50.8 mm and a length of 31 mm (which is an unprecedented length of not less than 30 mm) could be obtained.

### Advantages of the Fourth Embodiment

According to the fourth preferred embodiment described above, similarly to the fourth preferred embodiment, the internal stress in GaN ingot is remarkably relaxed, so that the GaN ingot with an unprecedented long length can be obtained, the cost reduction can be achieved, and the high quality GaN ingot and GaN substrate can be obtained.

Further, when a growth of ingot was tried at the growth condition similar to that of the fourth preferred embodiment except that the seed substrate of 100 μm in thickness was used, it was confirmed that also in this case an ingot with a diameter of 50.8 mm and the longest length of 31 mm and no cracks in a portion except 3 mm from the outermost can be obtained.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

For example, the following modifications and alternative constructions can be adopted.
(1) In each preferred embodiment, a case that a GaN substrate is obtained as a nitride semiconductor substrate has been explained, but the invention is not limited to the case, the invention can be applied to a case that a single crystal free-standing substrate is obtained, the free-standing substrate comprising a mixed crystal such as AlN and AlGaN, or. InGaN and AlInGaN. It is assumed that the condition for obtaining a good ingot is different from that of the GaN substrate, but the technical idea of the invention can be also applied to other substance systems adopting a similar growth system.
(2) In each preferred embodiment, a case that a nitride semiconductor ingot and a nitride semiconductor substrate are obtained by the HVPE method has been explained, but the invention is not limited to the case, they can be also obtained by various growth methods such as the metal-organic vapor phase epitaxy (MOVPE) method, a molecular beam epitaxy (MBE) method, and a flux method using Na etc.

III group nitride semiconductor substrate obtained due to the invention can be widely used as a substrate for a nitride semiconductor device.

What is claimed is:

1. A nitride semiconductor ingot, comprising:
a nitride semiconductor;
a length of more than 20 mm; and
a diameter of not less than 50.8 mm,
wherein the nitride semiconductor ingot includes no cracks in a portion except 3 mm from an outermost thereof.

2. The nitride semiconductor ingot according to claim 1, further comprising:
a minimum value in dislocation density being not more than 1.5×10⁶ cm⁻².

3. A nitride semiconductor substrate, comprising:
a diameter of not less than 25.4 mm; and
a thickness of not less than 0.2 mm,
wherein the substrate is produced by slicing a nitride semiconductor ingot, and
the nitride semiconductor ingot comprises a nitride semiconductor, a length of more than 20 mm, and a diameter of not less than 50.8 mm, wherein the nitride semiconductor ingot includes no cracks in a portion except 3 mm from an outermost thereof.

4. A nitride semiconductor substrate, comprising:
a diameter of not less than 25.4 mm; and
a thickness of not less than 0.2 mm,
wherein the substrate is produced by slicing a nitride semiconductor ingot,
the nitride semiconductor ingot comprises a nitride semiconductor, a length of more than 20 mm, and a diameter of not less than 50.8 mm, wherein the nitride semiconductor ingot includes no cracks in a portion except 3 mm from an outermost thereof, and
the nitride semiconductor substrate further comprises an off-angle variation of not more than 0.05 degrees in a plane of the substrate, where the off-angle variation is defined as a difference between a maximum value and a minimum value of off-angle in the plane.

5. The nitride semiconductor substrate according to claim 4 further comprising:
a dislocation density being not more than 1.5×10^{6 cm}⁻².

6. A method for making a nitride semiconductor ingot, comprising the steps of:
disposing a seed substrate comprising a thickness of 100 μm to 250 μm in a growth reactor; and
forming a nitride semiconductor on the seed substrate to grow a nitride semiconductor ingot,
wherein the nitride semiconductor ingot comprises a length of more than 20 mm and a diameter of not less than 50.8 mm, and the nitride semiconductor ingot includes no cracks in a portion except 3 mm from an outermost thereof.

7. A method for making a nitride semiconductor ingot, comprising the steps of:
disposing a seed substrate comprising a curvature radius in lattice plane warpage of not less than 20 m in a growth reactor; and
forming a nitride semiconductor on the seed substrate to grow a nitride semiconductor ingot,
wherein the nitride semiconductor ingot comprises a length of more than 20 mm and a diameter of not less than 50.8 mm, and the nitride semiconductor ingot includes no cracks in a portion except 3 mm from an outermost thereof.

8. A method for making a nitride semiconductor ingot, comprising the steps of:
disposing a seed substrate comprising a dislocation density of not more than 2×10⁶ cm⁻² in a growth reactor; and
forming a nitride semiconductor on the seed substrate to grow a nitride semiconductor ingot,
wherein the nitride semiconductor ingot comprises a length of more than 20 mm and a diameter of not less than 50.8 mm, and the nitride semiconductor ingot includes no cracks in a portion except 3 mm from an outermost thereof.

9. A method for making a nitride semiconductor ingot, comprising the steps of:
disposing a seed substrate in a growth reactor;
disposing a Ga (gallium) in the growth reactor and introducing an HCl gas therein;
introducing an NH₃ in the growth reactor;
controlling a temperature condition such that a temperature at a GaCl generation portion where a GaCl is generated from the HCl and the Ga is substantially equal to a temperature at a growth portion where a GaN is deposited in the growth reactor, and
growing the nitride semiconductor ingot on the seed substrate under the temperature condition, the nitride semiconductor ingot comprising a length of more than 20 mm and a diameter of not less than 50.8 mm and including no cracks in a portion except 3 mm from an outermost thereof.

10. A method for making a nitride semiconductor ingot, comprising the steps of:
disposing a seed substrate in a growth reactor;
introducing a GaCl in the growth reactor;
introducing an NH₃ in the growth reactor;
controlling a growth rate condition such that a variation in growth rate of the ingot to be grown based on a supply of the GaCl and the NH₃ in the growth reactor is not more than 5%, and
growing the nitride semiconductor ingot on the seed substrate under the growth rate condition, the nitride semiconductor ingot comprising a length of more than 20 mm and a diameter of not less than 50.8 mm and including no cracks in a portion except 3 mm from an outermost thereof.

11. The method for making a nitride semiconductor ingot according to claim 6, wherein:
the grown nitride semiconductor ingot comprises a minimum value in dislocation density of not more than 1.5×10⁶ cm⁻².

12. The method for making a nitride semiconductor ingot according to claim 7, wherein:
the grown nitride semiconductor ingot comprises a minimum value in dislocation density of not more than 1.5×10⁶ cm⁻².

13. The method for making a nitride semiconductor ingot according to claim 8, wherein:
the grown nitride semiconductor ingot comprises a minimum value in dislocation density of not more than 1.5×10⁶ cm⁻².

14. The method for making a nitride semiconductor ingot according to claim 9, wherein:
the grown nitride semiconductor ingot comprises a minimum value in dislocation density of not more than 1.5×10⁶ cm⁻².

15. The method for making a nitride semiconductor ingot according to claim 10, wherein:
the grown nitride semiconductor ingot comprises a minimum value in dislocation density of not more than 1.5×10⁶ cm⁻².
